(19) United States
(12) Patent Application Publication
(10) Pub. No.: US 2012/0160169 A1
(43) Pub. Date: Jun. 28, 2012

(54) FILM FORMING APPARATUS

(75) Inventors: Harunari HASEGAWA, Nirasaki City (JP); Kippei SUGITA, Nirasaki City (JP); Makoto TAKAHASHI, Oshu-shi (JP)

(73) Assignee: TOKYO ELECTRON LIMITED, Tokyo (JP)

(21) Appl. No.: 13/334,774

(22) Filed: Dec. 22, 2011

(30) Foreign Application Priority Data
Dec. 22, 2010 (JP) 2010-286406

(51) Int. Cl. C23C 16/46

(52) U.S. Cl. 118/725

(57) ABSTRACT

Provided is a film forming apparatus for forming a polyimide film on a substrate by supplying a first raw material gas formed as aromatic acid dianhydride and a second raw material gas formed as aromatic diamine to the substrate maintained within a film forming container, and thermally polymerizing the supplied first and second raw material gases on a surface of the substrate. The apparatus includes: a substrate maintaining unit within the film forming container; a substrate heating unit configured to heat the substrate; a supply mechanism within the film forming container, configured to include a supply pipe with supply holes for supplying the first and second raw material gases to the interior of the film forming container through the supply holes; and a controller configured to control the substrate maintaining unit, the substrate heating unit, and the supply mechanism.

### CROSS-REFERENCE TO RELATED APPLICATION

This application claims the benefit of Japanese Patent Application No. 2010-286406, filed on Dec. 22, 2010, in the Japan Patent Office, the disclosure of which is incorporated herein in its entirety by reference.

### TECHNICAL FIELD

The present disclosure relates to a film forming apparatus for forming a film on a substrate.

### BACKGROUND

Recently, material used for a semiconductor device has extended from inorganic material to organic material, and the characteristics of a semiconductor device or a fabrication process can be further optimized by using the special characteristics of the organic material, which are not present in the inorganic material.

One such organic material is polyimide. Polyimide has high adhesion and low leakage current. Thus, a polyimide film obtained by forming polyimide on a surface of a substrate may be used as an insulating layer, and may also be used as an insulating layer in a semiconductor device.

As a method for forming such a polyimide film, there is known a film forming method based on deposition polymerization using, for example, pyromellitic dianhydride (hereinafter, abbreviated as “PMDA”) and 4,4′-diaminodiphenylether including, for example, 4,4′-oxydianiline (hereinafter, abbreviated as “ODA”) as raw material monomers. The deposition polymerization is a method for thermally polymerizing PMDA and ODA used as raw material monomers on a surface of a substrate. In the related art, there is disclosed a film forming method for forming a polyimide film by evaporating the monomers of PDMA and ODA with a carburetor, supplying the evaporated vapor of each of the PDMA and ODA to a deposition polymerization chamber, and deposition-polymerizing the same on the substrate.

In order to form a polyimide film having excellent film quality by using deposition polymerization at a low cost and within a short time, it is required to continuously supply a fixed amount of vaporized PMDA (hereinafter, referred to as “PMDA gas”) and the vaporized ODA (hereinafter, referred to as “ODA gas”) to the substrate. Thus, a film forming apparatus for forming a polyimide film preferably includes a supply mechanism for supplying raw material gases composed of the PMDA gas and the ODA gas into a film forming container.

However, a film forming apparatus for forming a polyimide film by supplying the PMDA gas and the ODA gas to the substrate has the following problems.

In order to form a polyimide film on the surface of the substrate by supplying the PMDA gas and the ODA gas, a monomer of PMDA and a monomer of ODA are required to be thermally polymerized on the surface of the substrate. However, when the temperature of the substrate is changed, the film formation rate of the polyimide film is changed, degrading uniformity of film thickness, film quality, or the like of the polyimide film within the plane of the substrate.

Also, the foregoing issue is common even in the case where a polyimide film is formed by supplying a raw material gas formed as an aromatic acid dianhydride including a PMDA gas and a raw material gas formed as an aromatic diamine including an ODA gas to the substrate.

### SUMMARY

According to one aspect of the present disclosure, there is provided a film forming apparatus for forming a polyimide film on a substrate by supplying a first raw material gas formed as aromatic acid dianhydride and a second raw material gas formed as aromatic diamine to the substrate maintained within a film forming container, and thermally polymerizing the supplied first and second raw material gases on a surface of the substrate. The apparatus includes: a substrate maintaining unit configured to maintain the substrate within the film forming container; a substrate heating unit configured to heat the substrate maintained in the substrate maintaining unit; a supply mechanism installed within the film forming container, and configured to include a supply pipe with supply holes for supplying the first and second raw material gases to the interior of the film forming container through the supply holes; and a controller configured to control the substrate maintaining unit, the substrate heating unit, and the supply mechanism. The controller supplies the first and second raw material gases by the supply mechanism and simultaneously heats the substrate maintained in the substrate maintaining unit within a temperature range in which thermal polymerization takes place, by the substrate heating unit, to control a film formation rate of the polyimide film.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a vertical sectional view schematically showing a film forming apparatus according to a first embodiment of the present disclosure.

FIG. 2 is a perspective view schematically showing a loading area.

FIG. 3 is a view showing a state of a wafer W of a rear batch when a wafer W of a front batch is formed within a film forming container.

FIG. 4 is a perspective view schematically showing an example of a boat.

FIG. 5 is a sectional view showing a state in which a double-plate unit is mounted in the boat.

FIG. 6 is a side view schematically showing an example of a movement mounting mechanism.

FIG. 7 is a first side view illustrating the order in which the movement mounting mechanism configures the double-plate unit and transfers it.

FIG. 8 is a second side view illustrating the order in which the movement mounting mechanism configures the double-plate unit and transfers it.

FIG. 9 is a third side view illustrating the order in which the movement mounting mechanism configures the double-plate unit and transfers it.

FIG. 10 is an enlarged sectional view of a portion in which an upper fork grasps an upper wafer W when a lower fork has two sheets of wafers W mounted thereon through a support ring.

FIG. 11 is a sectional view schematically showing the configuration of the film forming container, a supply mechanism, and an exhaust mechanism.

FIG. 12 is a side view illustrating an example of an injector.

FIG. 13 is a sectional view taken along line A-A in FIG. 12.

FIG. 14 is a front view of the injector illustrated in FIG. 12.

FIG. 15 is a flowchart illustrating a sequential process including the film forming process using the film forming apparatus according to the first embodiment.

FIG. 16 is a graph schematically showing film formation rate (film thickness) of a polyimide film formed on the wafer W and wafer temperature dependency of a deviation of the film formation rate within a plane.

FIG. 17 is a graph showing film formation rate (film thickness) of a polyimide film formed on each wafer W maintained in a boat when the temperature of a supply pipe heating mechanism is changed.

FIG. 18 is a graph showing film formation rate (film thickness) of the polyimide film formed on each wafer W maintained in the boat along with a deviation within a plane of the film formation rate, and a wafer temperature in a comparative example.

FIG. 19 is a side view showing an injector according to a first modification of the first embodiment.

FIG. 20 is a sectional view taken along line A-A in FIG. 19.

FIG. 21 is a front view of an injector illustrated in FIG. 19.

FIG. 22 is a side view showing an injector according to a second modification of the first embodiment.

FIG. 23 is a vertical sectional view schematically showing a film forming apparatus according to a second embodiment.

FIG. 24 is a sectional view schematically showing a configuration of a film forming container, a supply mechanism, and an exhaust mechanism of the film forming apparatus illustrated in FIG. 23.

### DETAILED DESCRIPTION

A first embodiment of the present disclosure will now be described in detail with reference to the drawings.

### First Embodiment

First, a film forming apparatus according to a first embodiment of the present disclosure will be described. The film forming apparatus according to the present embodiment forms a polyimide film on a substrate installed within a film forming container by supplying a first raw material gas obtained by vaporizing a first raw material formed as aromatic acid dianhydride and a second raw material gas obtained by vaporizing a second raw material formed as aromatic diamine to the substrate.

Preferably, the aromatic acid dianhydride is pyromellitic dianhydride (PMDA), and the aromatic diamine is, for example, 4,4′-diaminodiphenylether including 4,4′-oxydianiline (ODA). The substrate on which a polyimide film is formed may be, for example, a semiconductor wafer (hereinafter, referred to as a “wafer W”). Hereinafter, the film forming apparatus for forming a polyimide film on the wafer W installed within the film forming container by supplying, for example, a vaporized PMDA gas and a vaporized ODA gas to the wafer W will be described.

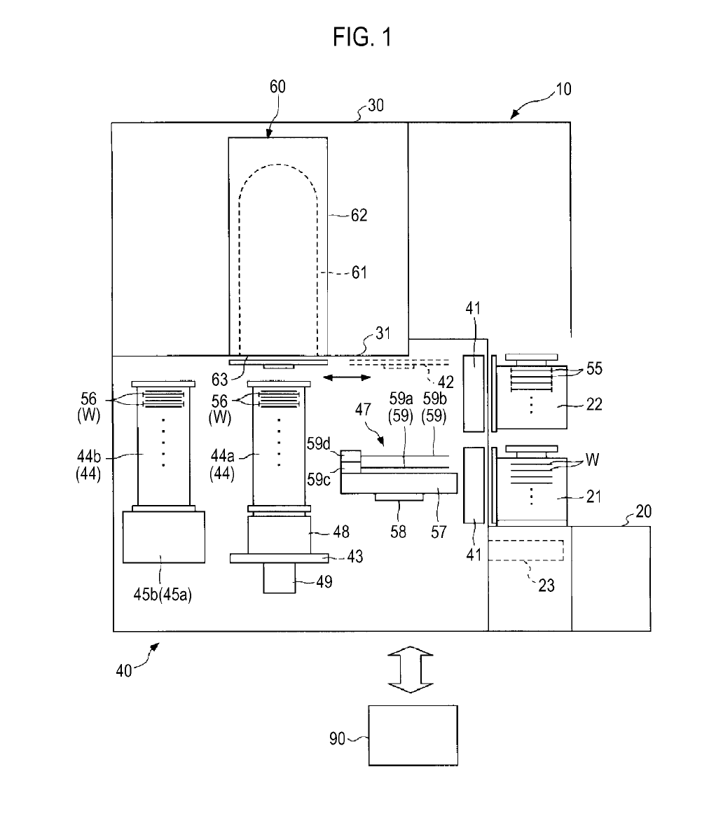

First, a film forming apparatus according to the first embodiment of the present disclosure will be described with reference to FIGS. 1 to 6.

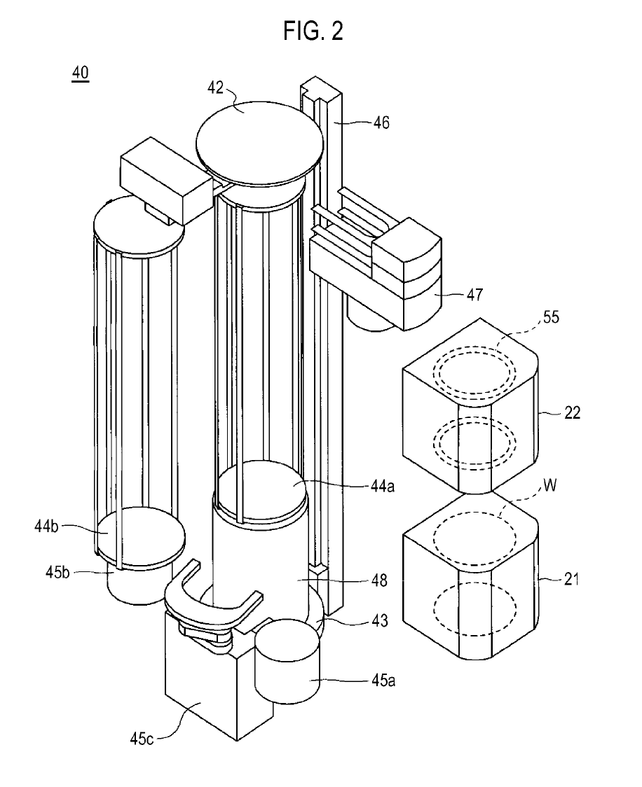

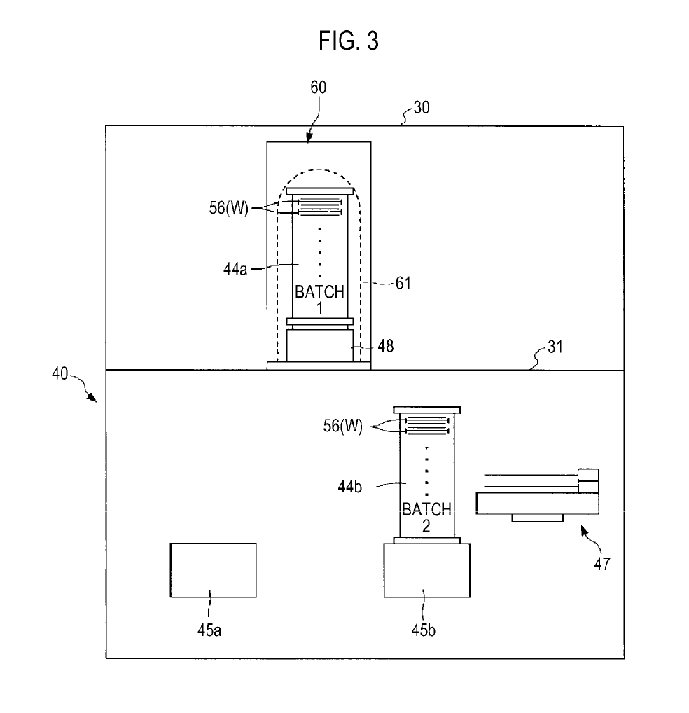

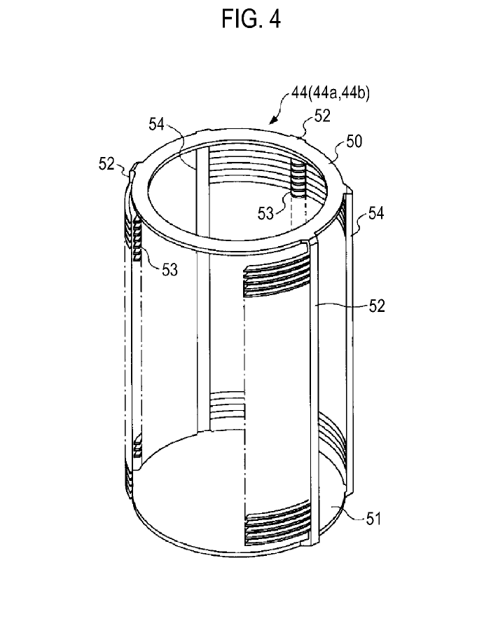

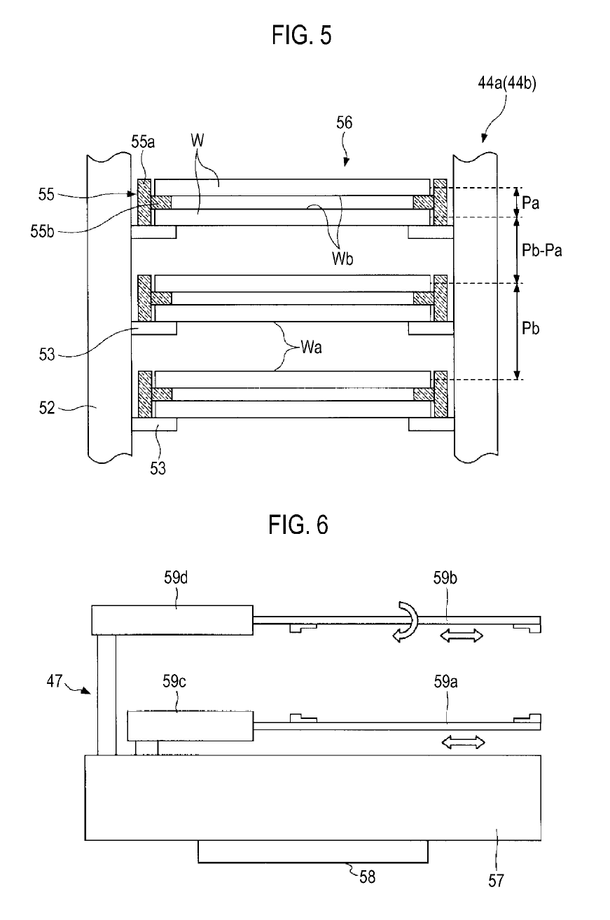

FIG. 1 is a vertical sectional view schematically showing a film forming apparatus 10 according to the present embodiment. FIG. 2 is a perspective view schematically showing a loading area 40 illustrated in FIG. 1. FIG. 3 is a view showing a state of a wafer W of a rear batch (batch 2) when a wafer W of a front batch (batch 1) is formed within a film forming container. FIG. 4 is a perspective view schematically showing an example of a boat 44. FIG. 5 is a sectional view showing a state in which a double-plate unit 56 is mounted in the boat 44. FIG. 6 is a side view schematically showing an example of a movement mounting mechanism 47.

The film forming apparatus 10 has a loading table (load port) 20, a housing 30, and a controller 90.

The loading table (load port) 20 is installed at a front portion of the housing 30. The housing 30 has a loading area (operation area) 40 and a film forming container 60. The loading area 40 is installed at a lower portion within the housing 30, and the film forming container 60 is installed above the loading area 40 within the housing 30. In addition, a base plate 31 is formed between the loading area 40 and the film forming container 60. Also, a supply mechanism 70 (to be described later) is installed to be connected with the film forming container 60.

The base plate 31 is a base plate made of, for example, SUS, for installing a reaction tube 61 (to be described later) of the film forming container 60, and includes an opening (not shown) for allowing the reaction tube 61 to be upwardly inserted from a lower side.

The loading table (load port) 20 is to load or unload a wafer W into or from the housing 30. The loading table (load port) 20 has a receiving container 21 mounted thereon. The receiving container 21 is an airtight receiving container (hoop) having a cover (not shown) detachably attached to a front side thereof, in which a plurality of sheets of wafers W, for example, about 50 sheets of wafers W, can be received at certain intervals.

Also, in the present embodiment, the loading table (load port) 20 may serve to load or unload support rings 55 (to be described later) into or from the housing 30. A receiving container 22 may be mounted on the loading table (load port) 20. The receiving container 22 is an airtight receiving container (hoop) having a cover (not shown) detachably attached to a front side thereof, in which a plurality of sheets of support rings 55 (to be described later), for example, about 25 sheets of support rings 55, can be received at certain intervals.

Also, an alignment device (aligner) 23 for aligning cutout portions (e.g., notches) formed on an outer circumference of the wafers W, which have been moved and mounted by a movement mounting mechanism 47 (to be described later), in one direction may be installed at a lower side of the loading table 20.

The loading area (operation area) 40 serves to movably mount a wafer W between the receiving container 21 and a boat 44 (to be described later) and load the boat 44 into the film forming container 60, and unload the boat 44 from the film forming container 60. A door mechanism 41, a shutter mechanism 42, a cover 43, the boat 44, bases 45a and 45b, a lifting mechanism 46, and the movement mounting mechanism 47 are installed in the loading area 40.

Also, the cover 43 and the boat 44 correspond to a substrate maintaining unit in the present disclosure.

The door mechanisms 41 remove the covers of the receiving containers 21 and 22 to allow the interiors of the receiving containers 21 and 22 to communicate with the interior of the loading area 40.

The shutter mechanism 42 is installed at an upper portion of the loading area 40. The shutter mechanism 42 is installed to cover (or shut) an opening 63 of the film forming container 60 (to be described later) in order to restrain or prevent heat within a high temperature furnace from being discharged to the loading area 40 from the opening 63 when the cover 43 is not covering the opening 63.

The cover 43 has a warming container 48 and a rotary mechanism 49. The warming container 48 is installed on the cover 43. The warming container 48 serves to keep the boat 44 warm by preventing the boat 44 from being cooled by heat transfer with the cover 43. The rotary mechanism 49 is installed at a lower portion of the cover 43. The rotary mechanism 49 rotates the boat 44. A rotational shaft of the rotary mechanism 49 is installed to airtightly penetrate the cover 43 to rotate a rotary table (not shown) disposed on the cover 43.

As shown in FIG. 2, the lifting mechanism 46 lifts or lowers the cover 43 when the boat 44 is loaded into the film forming container 60 from the loading area 40 or unloaded therefrom. In addition, when the cover 43 lifted by the lifting mechanism 46 is loaded within the film forming container 60, the cover 43 contacts with the opening 63 (to be described later) to hermetically close the opening 63. Further, the boat 44 loaded on the cover 43 is able to rotatably maintain the wafer W within a horizontal plane within the film forming container 60.

Also, the film forming apparatus 10 may have a plurality of boats 44. Hereinafter, in the present embodiment, an example in which two boats 44 are provided will be described with reference to FIG. 2.

Boats 44a and 44b are installed in the loading area 40. Also, the bases 45a and 45b and a boat transfer mechanism 45c are installed in the loading area 40. The bases 45a and 45b are load ports to which the boats 44a and 44b are moved from the cover 43 to be mounted thereon, respectively. The boat transfer mechanism 45c serves to move the boats 44a and 44b to the bases 45a and 45b from the cover 43 to be mounted thereon.

As shown in FIG. 3, while the boat 44a with wafers W of a front batch (batch 1) mounted thereon is loaded into the film forming container 60 and a film is formed, wafers W of a rear batch (batch 2) may be moved and mounted from the receiving container 21 to the boat 44b in the loading area 40. Accordingly, when the film formation process of the wafers W of the front batch (batch 1) is terminated, the boat 44b with the wafers W of the rear batch (batch 2) mounted thereon can be loaded into the film forming container 60 immediately after the boat 44a is unloaded from the film forming container 60. As a result, a time (tact time) required for film formation processing can be shortened to reduce fabrication costs.

The boats 44a and 44b may be made of, for example, quartz, and wafers having a large diameter, for example, wafers W having a diameter of 300 mm, may be mounted at certain intervals (pitch width) in a vertical direction in a horizontal state. As shown in FIG. 4, the boats 44a and 44b are formed by interposing a plurality of pillars, for example, three pillars 52, between a ceiling plate 50 and a bottom plate 51. A hook portion 53 for maintaining wafers W may be installed on the pillars 52. Also, auxiliary columns 54 may be appropriately installed along with the pillars 52.

Also, as shown in FIG. 5, with regard to the boats 44a and 44b, a plurality of wafers W may be maintained in a vertical direction such that they vertically neighbor with rear surfaces Wb thereof facing each other or with surfaces Wa thereof facing each other. At the same time, the interval between two sheets of wafers W, which vertically neighbor with rear surfaces Wb facing each other is narrower than the interval between two sheets of wafers W which vertically neighbor with surfaces Wa thereof facing each other. Hereinafter, for the present embodiment, an example in which the wafers W that vertically neighbor each other are mounted on the boats 44a and 44b such that their rear surfaces Wb face each other through a support ring 55 will be described.

A double-plate unit 56 configured to support two sheets of wafers W may be maintained on the hook portions 53 of the boats 44a and 44b. The double-plate unit 56 supports the two sheets of wafers W such that the rear surfaces Wb thereof face each other by supporting circumferential portions of the wafers W by the support ring 55. It is assumed that the interval of the two sheets of wafers W supported such that the rear surfaces Wb thereof face each other in one double-plate unit 56 is Pa and the interval at which the double-plate units 56 are maintained in the vertical direction, namely, the interval between the hook portions 53 is Pb. At this time, the interval of two sheets of wafers W that neighbor vertically with surfaces Wa thereof facing each other is Pb-Pa. In this arrangement, preferably, Pa is smaller than Pb-Pa. Namely, it is preferred that a plurality of wafers W are maintained in the vertical direction such that the interval Pa of the two sheets of wafers W that vertically neighbor with rear surfaces Wb thereof facing each other is narrower than the interval Pb-Pa of the two sheets of wafers W that vertically neighbor with surfaces Wa thereof facing each other.

The support ring 55 includes a circular ring portion 55a having an inner diameter which is equal to or slightly greater than the wafer W, and a spacer portion 55b installed at the center along an inner circumference of the circular ring portion 55a, excluding upper and lower end portions of the circular ring portion 55a, to form the interval between two sheets of wafers W. The spacer portion 55b serves to seal a gap between the two sheets of wafers W that vertically neighbor with rear surfaces Wb thereof facing each other when a film is formed within the film forming container 60. Also, the spacer portion 55b serves to prevent a raw material gas from being introduced to the gap between two sheets of wafers W that vertically neighbor with rear surfaces Wb thereof facing each other and a film from being formed on the rear surface Wb of the wafer W. The support ring 55 may be made of, for example, quartz.

Further, the spacer portion 55b of the support ring 55 corresponds to a blocking member in the present embodiment.

As shown in FIG. 5, the wafer W with a rear surface Wb as an upper surface (namely, the surface Wa as a lower surface) is supported on the hook portion 53. The support ring 55 is supported by the hook portion 53 in a state in which a lower surface of the circular ring portion 55a is in contact with the hook portion 53. Also, the wafer W with the rear surface Wb as a lower surface (namely, the surface Wa as an upper surface) is supported on the spacer portion 55b of the support ring 55.

Here, in one double-plate unit 56, the interval Pa between two sheets of wafers W supported such that rear surfaces Wb thereof face each other may be, for example, 2 mm, and the interval Pb at which the double-plate unit 56 is maintained in the vertical direction (interval between the hook portions 53) may be, for example, 11 mm. Then, the interval Pb-Pa of two sheets of wafers W that vertically neighbor with surfaces Wa thereof facing each other may be 9 mm. However, assuming that the wafers W are supported such that the interval between two neighboring wafers W in the plurality of wafers W is equal without changing the number of wafers mounted on the boat 44, the interval between two sheets of wafers W that vertically neighbor is 5.5 mm, half of 11 mm, which is smaller than 9 mm. Thus, according to the present embodiment, since the wafers W are supported such that the rear surfaces Wb thereof face each other by using the double-plate unit 56, the gap between the surface Wa of one wafer W and the surface Wa of the other wafer W can be increased, so that a sufficient amount of raw material gas can be supplied to the surface Wa of the wafer W.

The movement mounting mechanism 47 serves to move and mount the wafers W or the support ring 55 between the receiving containers 21 and 22 and the boats 44a and 44b. The movement mounting mechanism 47 includes a base 57, a lifting arm 58, and a plurality of forks (movement mounting plates) 59. The base 57 is installed to be lifted and lowered and to gyrate. The lifting arm 58 is installed to be movable (liftable) in a vertical direction by a ball thread, or the like, and the base 57 is installed to horizontally gyrate on the lifting arm 58.

Also, for example, the movement mounting mechanism 47 may have a lower fork 59a which can be horizontally moved and an upper fork 59b which can be horizontally moved and vertically flipped. An example of the movement mounting mechanism 47 is illustrated in the side view of FIG. 6.

The lower fork 59a is installed to move to and from the boats 44a and 44b for mounting the double-plate unit 56 thereon by a moving body 59c, and to transfer the double-plate unit 56 to and from the boats 44a and 44b. Meanwhile, the upper folk 59b is installed to be horizontally moved by the moving body 59d and to move to and from the receiving container 21 that receives the wafers W, and to transfer the wafers W to and from the receiving container 21. Also, the upper fork 59b is installed to move to and from the receiving container 22 that receives the support ring 55 by the moving body 59d and to transfer the support ring 55 to and from the receiving container 22.

Further, the movement mounting mechanism 47 may have a plurality of sheets of lower forks 59a and a plurality of sheets of upper forks 59b.

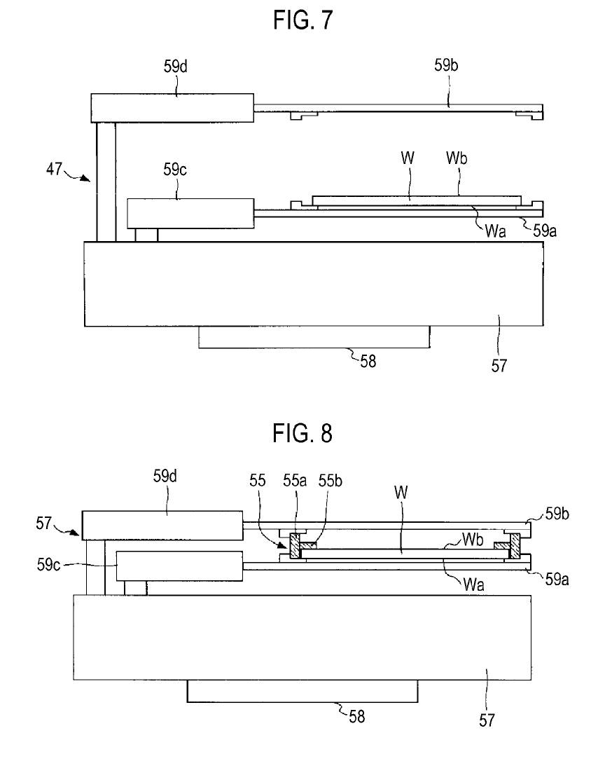

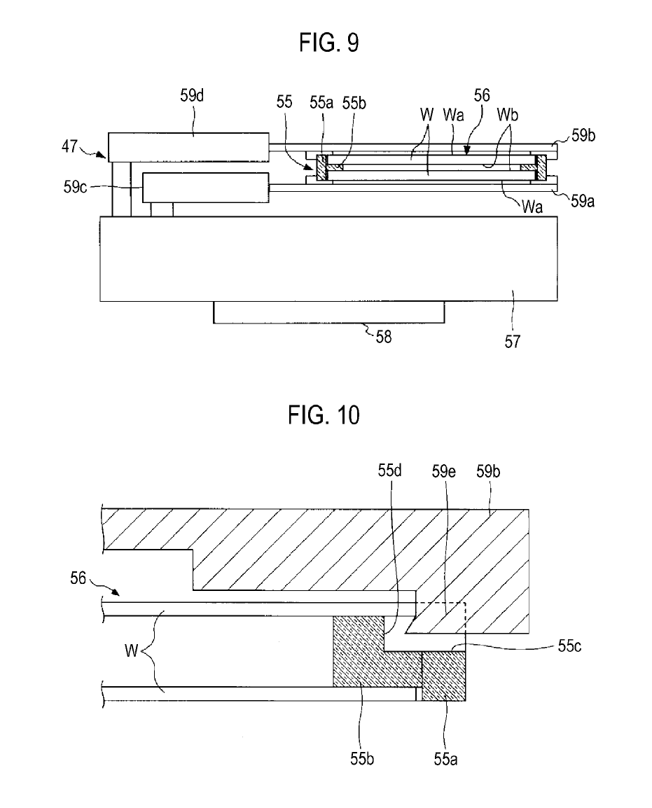

FIGS. 7 to 9 are side views showing the order in which the movement mounting mechanism 47 configures the double-plate unit 56 and performs transferring. First, the upper fork 59b moves into the receiving container 21, takes the wafer W received in the receiving container 21, moves back from the interior of the receiving container 21, is vertically flipped while maintaining the wafer W, and transfers the wafer W as a lower wafer W to the lower fork 59a (FIG. 7). Next, the upper fork 59b in the vertically flipped state moves to the receiving container 22, takes the support ring 55 received in the receiving container 22, moves back from the interior of the receiving container 22, and loads the support ring 55 on the lower wafer W maintained by the lower fork 59a (FIG. 8). Then, the upper fork 59b in the vertically flipped state moves into the receiving container 21, takes the wafer W received in the receiving container 21, moves back from the interior of the receiving container 21, and loads the wafer W as an upper wafer W on the support ring 55 maintained by the lower fork 59a (FIG. 9).

FIG. 10 is an enlarged sectional view of a portion in which the upper fork 59b grasps the upper wafer W when the lower fork 59a has two sheets of wafers W mounted thereon through the support ring 55. The illustration of the lower fork 59a is omitted in FIG. 10.

The circular ring portion 55a and the spacer portion 55b constitute the support ring 55, and as shown in FIG. 10, cutout portions 55c and 55d may be formed at a portion having the possibility of being in contact with the support ring 55 when the upper fork 59b loads the second sheet of wafer W to thus prevent interference with the hook portion 59e of the upper fork 59b. However, even at the portions where the cutout portions 55c and 55d are formed, the spacer portion 55b is preferably installed to block the gap between the two sheets of wafers W. Accordingly, a raw material gas can be reliably prevented from being introduced between the two sheets of wafers W mounted such that rear surfaces Wb thereof face each other and from forming a film on the rear surface Wb of the wafer W.

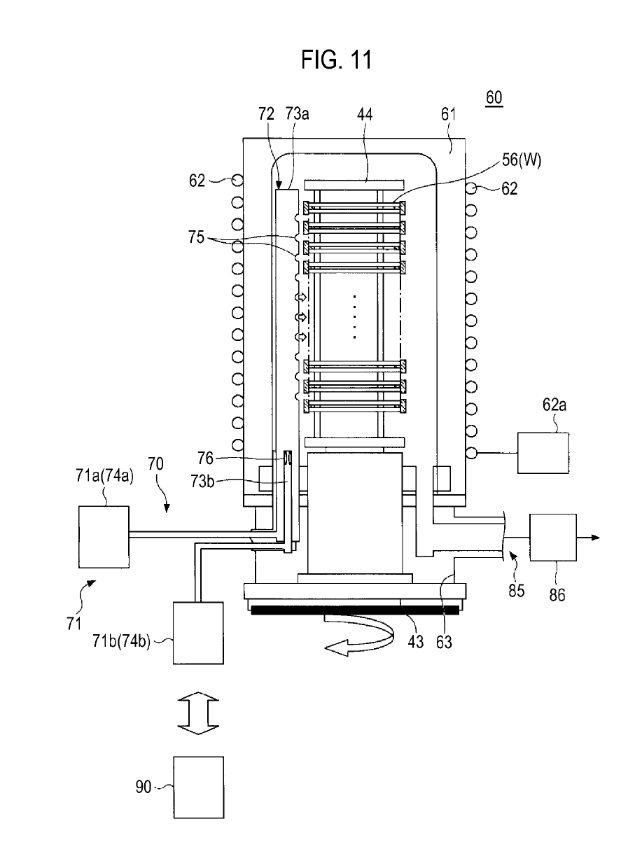

FIG. 11 is a sectional view schematically showing the configuration of the film forming container 60, the supply mechanism 70, and an exhaust mechanism 85.

The film forming container 60 may be a vertical furnace for accommodating, for example, a plurality of target substrates, for example, the wafers W in the shape of a circular thin plate, and performing certain processing, for example, CVD, or the like. The film forming container 60 has a reaction pipe 61 and a heater (substrate heating unit) 62.

The reaction pipe 61 is made of, for example, quartz, has a vertically long shape, and has an opening 63 formed at a lower end portion thereof. The heater (substrate heating unit) 62 is installed to surround the reaction pipe 61, has a heating controller 62a, and heats and controls the interior of the reaction pipe 61 by the heating controller 62a to have a certain temperature, for example, 300 to 1200 degrees C. Also, as described later, the heater (substrate heating unit) 62 may be divided into a plurality of zones, and the temperature of each zone may be independently controlled.

The supply mechanism 70 includes a raw material gas supply unit 71 and an injector 72 installed within the film forming container 60. The injector 72 includes a supply pipe 73a. The raw material gas supply unit 71 is connected with the supply pipe 73a of the injector 72.

In the present embodiment, the supply mechanism 70 may have a first raw material gas supply unit 71a and a second raw material gas supply unit 71b. In this case, the first raw material gas supply unit 71a and the second raw material gas supply unit 71b are connected with the injector 72 (supply pipe 73a). The first raw material gas supply unit 71a may have a first carburetor 74a for vaporizing, for example, a PMDA raw material, and supply a PMDA gas. Also, the second raw material gas supply unit 71b may have a second carburetor 74b for vaporizing, for example, an ODA raw material, and supply an ODA gas.

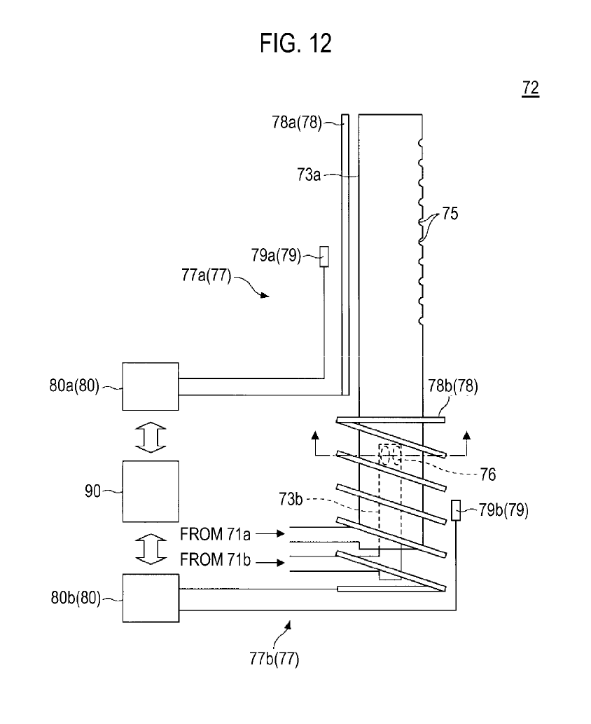

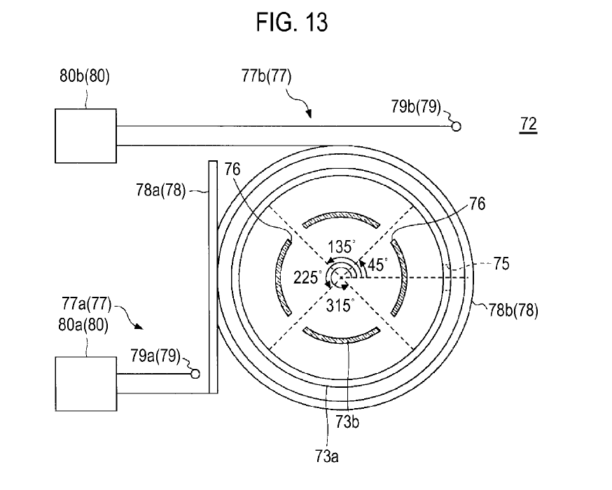

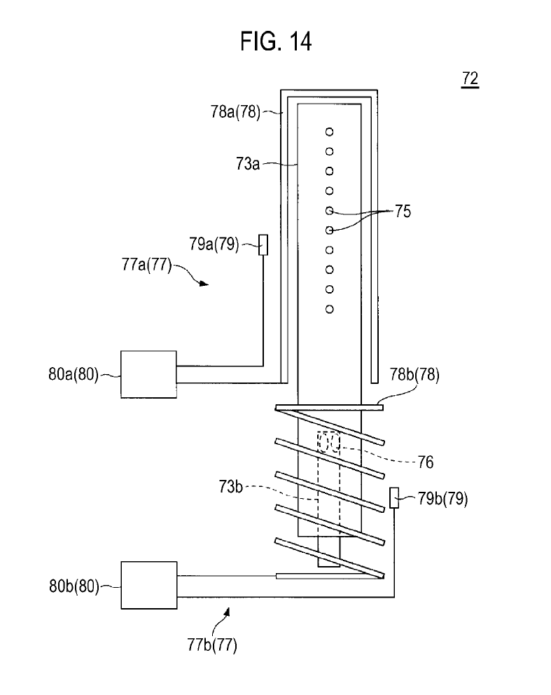

FIG. 12 is a side view illustrating an example of the injector 72. FIG. 13 is a sectional view taken along line A-A in FIG. 12. FIG. 14 is a front view of the injector 72 illustrated in FIG. 12. FIG. 12 shows a front view of the injector 72 viewed from the side of the boat 44.

Supply holes 75 are formed on the supply pipe 73a so as to be open to the interior of the film forming container 60. The injector 72 supplies first and second raw material gases flowing in the supply pipe 73a to the film forming container 60 through the supply holes 75 from the raw material gas supply unit 71.

Also, in the present embodiment, an example in which the boat 44 maintains the plurality of wafers W at certain intervals in the vertical direction is described. Here, the supply pipe 73a may be installed to extend in the vertical direction. In addition, a plurality of supply holes 75 may be formed on the supply pipe 73a.

Further, the supply holes 75 may have various shapes such as a circular shape, an oval shape, a rectangular shape, and the like.

The injector 72 preferably includes an inner supply pipe. The inner supply pipe 73b may be accommodated in the vicinity of an upstream side of the supply pipe 73a, rather than at a portion where the supply holes 75 of the supply pipe 73 are formed. Also, an opening 76 may be formed in the vicinity of the end portion of the downstream side of the inner supply pipe 73b in order to supply any one of the first and second raw material gases to the inner space of the supply pipe 73a. By including the inner supply pipe 73b having such a structure, the first and second raw material gases can be sufficiently mixed in the inner space of the supply pipe 73a in advance before they are supplied to the interior of the film forming container 60 from the supply holes 75.

Also, hereinafter, the case in which the first raw material gas is supplied to the supply pipe 73a and the second raw material gas is supplied to the inner supply pipe 73b will be described as an example. However, the first raw material gas may be supplied to the inner supply pipe 73b and the second raw material gas may be supplied to the supply pipe 73a.

Further, the opening 76 may have various shapes such as a circular shape, an oval shape, a rectangular shape, and the like.

In the present embodiment, an example in which the plurality of wafers W are maintained at certain intervals in the vertical direction in the boat 44 is described. Here, the inner supply pipe 73b, along with the supply pipe 73a, may also be installed to extend in the vertical direction. Also, when the lower side is determined to be an upstream side and the upper side is determined to be a downstream side, the inner supply pipe 73b may be installed to be accommodated within the supply pipe 73a at a portion of the lower side, rather than the portion where the supply holes 75 of the supply pipe 73a are formed. In addition, the opening 76 may be formed to communicate with the inner space of the supply pipe 73a in the vicinity of the upper end portion of the inner supply pipe 73b.

The supply mechanism 70 makes, for example, the first raw material gas flow to the supply pipe 73a and, at the same time, makes the second raw material gas flow to the inner supply pipe 73b. Also, the supply mechanism 70 makes the second raw material gas flowing in the inner supply pipe 73b join with the supply pipe 73a through the opening 76, and supplies the first and second raw material gases in a mixed state into the film forming container 60 through the supply holes 75.

As shown in FIG. 13, a plurality of openings 76 may be formed in a circumferential direction of the inner supply pipe 73b in the section (horizontal section) perpendicular to the direction (vertical direction) in which the inner supply pipe 73b extends. Preferably, the openings 76 are formed in a different direction from the direction in which the supply holes 75 are formed on the supply pipe 73a when viewed from the section (when viewed from the plane) perpendicular to the direction in which the supply pipe 73a extends. Namely, preferably, all openings 76 are formed to face in a different direction from the direction toward the wafers W and the exhaust pipe 82. By disposing the opening 76 in this manner, the first and second raw material gases in a uniformly mixed state can be discharged from the supply holes 75.

In the example shown in FIG. 13, four openings 76 are formed by equal interval in the circumferential direction of the inner supply pipe 73b, and the direction in which the respective openings 76 are formed may preferably be at angles of 45°, 135°, 225°, 315°, respectively, with respect to the direction in which the supply holes 75 are formed. By disposing the opening 76 in this manner, the first and second raw material gases in a more uniformly mixed state can be discharged from the supply holes 75.

It is assumed that an outer diameter of the supply pipe 73a is, for example, 33 m, an inner diameter thereof is, for example, 29 mm, a hole diameter of the supply hole 75 is, for example, 2 mm, and the number of the formed supply holes 75 is, for example, 10. Also, it may be assumed that an outer diameter of the inner supply pipe 73b is, for example, 22 mm, an inner diameter thereof is, for example, 18 mm, and the hole diameter of the opening 76 formed at the angle of 45° may be, for example, 10 mm.

The injector 72 may include a supply pipe heating mechanism 77 for heating the supply pipe 73a. As shown in FIGS. 12 to 14, the supply pipe heating mechanism 77 may include a heater 78, a temperature sensor 79, and a heating controller 80. The supply pipe heating mechanism 77 serves to heat the first and second raw material gases flowing in the supply pipe 73a such that they have a temperature higher than a temperature range in which thermal polymerization takes place.

The heater 78 is configured as, for example, a resistance heating element. The heating controller 80 may measure a temperature by the temperature sensor 79, power to be supplied to the heater 78 is determined based on the measured temperature and a temperature preset by the controller 90 (to be described later), and the determined power is supplied to the heater 78. Accordingly, the supply pipe 73a can be heated at the preset temperature.

As shown in FIGS. 12 to 14, the heater 78, for example, may be installed at the opposite side of the boat 44 of the supply pipe 73a. Accordingly, the wafer W maintained in the boat 44 can be prevented from being heated by the supply pipe heating mechanism 77. Also, the temperature sensor 79 may be installed at the opposite side of the boat 44 of the supply pipe 73a. Accordingly, the temperature of the supply pipe 73a can be measured without being affected by the heated wafer W.

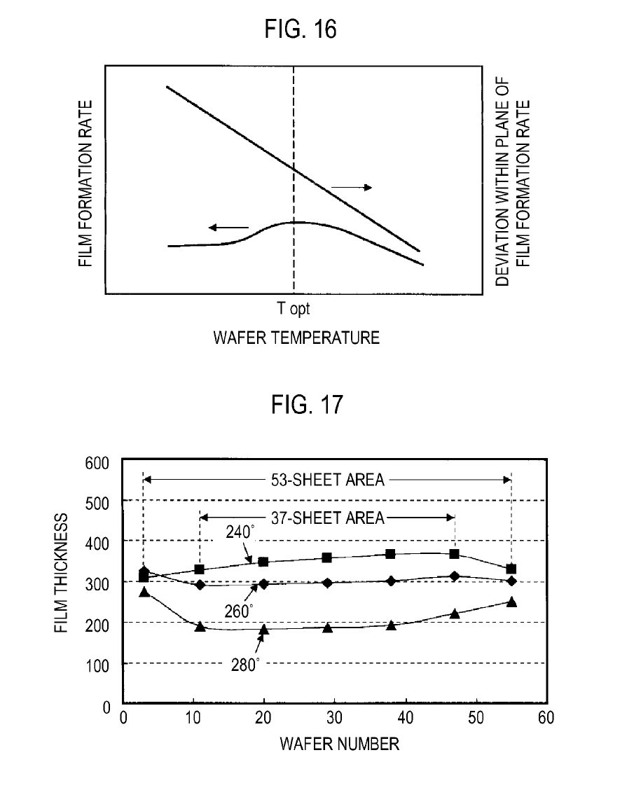

In this manner, since the supply pipe 73a is heated at a temperature higher than the temperature range in which the thermal polymerization takes place, the first and second raw material gases flowing in the supply pipe 73a can be heated at a temperature higher than the temperature range in which the thermal polymerization takes place. Meanwhile, as described later with reference to FIG. 16, within a certain temperature range, the film formation rate is reduced according to an increase in the temperature. Thus, the polyimide film generated according to the thermal polymerization of the first and second raw material gases can be restrained from being deposited on an inner wall of the supply pipe 73a or in the vicinity of the supply hole 75.

Also, the supply mechanism 70 may include a plurality of supply pipe heating mechanisms 77a and 77b which are disposed in a vertical direction and whose temperature can be independently controllable. The plurality of supply pipe heating mechanisms 77a and 77b may include heaters 78a and 78b, temperature sensors 79a and 79b, and heating controllers 80a and 80b, respectively. FIGS. 12 to 14 illustrate examples in which the supply mechanism 70 include two supply pipe heating mechanisms which are disposed in the vertical direction and whose temperatures can be independently controllable; namely, the upper supply pipe heating mechanism 77a and the lower supply pipe heating mechanism 77b.

The upper supply pipe heating mechanism 77a is disposed to heat a portion where the supply hole 75 of the supply pipe 73a is formed. The lower supply pipe heating mechanism 77b is disposed to heat a lower portion than the portion where the supply hole 75 of the supply pipe 73a is formed.

As shown in FIGS. 12 to 14, the upper heater 78a, for example, may be installed at the opposite side of the boat 44 where the supply hole 75 of the supply pipe 73a is formed. Accordingly, the wafer W maintained in the boat 44 can be restrained from being heated by the supply pipe heating mechanism 77a. Further, the upper temperature sensor 79a may also be installed at the opposite side of the boat 44 of the supply pipe 73a. Accordingly, the supply pipe 73a can be heated without having to provide power to the supply pipe heating mechanism 77a more than necessary.

The supply hole 75 is not formed at the portion of the supply pipe 73a where the lower heater 78b is installed. Thus, the lower heater 78b may be installed to surround a lower portion than the portion where the supply hole 75 of the supply pipe 73a is formed. Also, the lower temperature sensor 79b may be installed at a position close to the heated supply pipe 73a.

By the upper supply pipe heating mechanism 77a and the lower supply pipe heating mechanism 77b being installed in this manner, the supply pipe 73a is heated at a temperature higher than the temperature range in which thermal polymerization takes place. Thus, the first raw material gas and the second raw material gas flowing in some portions of the supply pipe 73a are also heated at a temperature higher than the temperature range in which the thermal polymerization takes place. Accordingly, the polyimide film generated according to thermal polymerization of the first and second raw material gases can be further restrained from being deposited on the inner wall of the supply pipe 73a or in the vicinity of the supply hole 75.

As shown in FIG. 11, the exhaust mechanism 85 includes an exhaust device 86. The exhaust mechanism 85 serves to exhaust gas from the interior of the film forming container 60.

The controller 90 includes, for example, an operation processing unit, a memory unit, and a display unit (not shown). The operation processing unit is, for example, a computer having a central processing unit (CPU). The memory unit is a computer-readable recording medium configured by, for example, a hard disk storing a program for executing various processing in the operation processing unit. The display unit is configured as, for example, a computer screen. The operation processing unit reads the program stored in the memory unit, transmits a control signal to each component constituting the boat 44 (substrate maintaining unit), the heating controller 62a of the heater (substrate heating unit) 62, the supply mechanism 70, the heating controller 80 of the supply pipe heating mechanism 77, and the exhaust mechanism 85, and executes film formation processing (to be described later) depending on the program.

Also, the controller 90 supplies the first and second raw material gases by the supply mechanism 70 and simultaneously heats the wafer W maintained in the boat 44 (substrate maintaining unit) within the temperature range in which the thermal polymerization takes place, by the heater (substrate heating unit) 62, thus controlling a film formation rate of the polyimide film as formed.

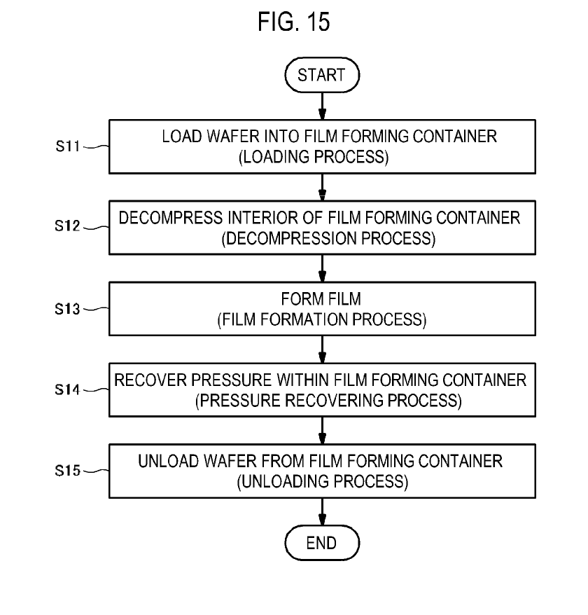

Next, film formation processing using the film forming apparatus according to the present embodiment will be described. FIG. 15 is a flowchart illustrating a sequential process including film formation processing using the film forming apparatus according to the present embodiment.

When the film formation processing starts, the wafer W is loaded into the film forming container 60 in step S11 (loading process). In the example of the film forming apparatus 10 illustrated in FIGS. 1 to 4, for example, the wafer W (double-plate unit 56) is mounted in the boat 44a from the receiving container 21 by the movement mounting mechanism 47 in the loading area 40, and the boat 44a with the wafer W (double-plate unit 56) mounted therein is loaded on the cover 43 by the boat transfer mechanism 45c. Then, the cover 43 with the boat 44a loaded thereon is lifted by the lifting mechanism 46 so as to be inserted into the film forming container 60, thus loading the wafer W.

Next, in step S12, the interior of the film forming container 60 is decompressed (decompression process). An exhaust capability of the exhaust device 86 or a flow rate adjustment valve (not shown) installed between the exhaust device 86 and the film forming container 60 is adjusted to increase an exhaust volume of exhausting the film forming container 60. Also, the interior of the film forming container 60 is decompressed from a certain pressure, for example, from atmospheric pressure (760 Torr), for example, to 0.3 Torr.

Thereafter, in step S13, a polyimide film is formed (film formation process).

By allowing the first raw material gas to be introduced to the supply pipe 73a from the first raw material gas supply unit 71a at a first flow rate F1, and the second raw material gas to be introduced to the inner supply pipe 73b from the second raw material gas supply unit 71b at a second flow rate F2, the first and second raw material gases mixed in a certain mixture ratio are supplied into the film forming container 60. Then, PMDA and ODA are polymerized on the surface of the wafer W to form a polyimide film.

The polymerization of PMDA and ODA in this case follows Chemical Formula 1 as follows:

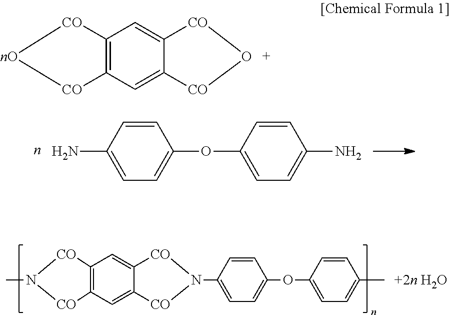

When the temperature of the wafer W is within a temperature range (e.g., about 200 degrees C.) in which thermal polymerization takes place as expressed by Chemical Formula 1, the film formation rate is reduced according to an increase in the temperature of the wafer W. One example of the reason why the film formation rate is reduced according to the increase in the temperature of the wafer W within the temperature range in which thermal polymerization takes place is believed to be that an average stay time of the PMDA gas is shorter than that of the ODA gas on the surface of the wafer.

It is assumed that the average stay time is an average adsorption time which is an average of time during which a PMDA monomer and an ODA monomer are adsorbed to the wafer. When separation activation energy is Ed and the number of vibrations of molecules perpendicular to the wafer surface is τ₀, the average adsorption time t can be obtained by Chemical Formula 2:

τ=τ₀exp(Ed/RT) [Chemical Formula 2]

Here, the separation activation energy Ed of the PMDA monomer can be 100 kJ/mol, and that of the ODA monomer can be 170 kJ/mol.

Table 1 shows the results of an average stay time (average adsorption time) of the PMDA gas and that of the ODA gas at respective wafer temperatures of 20 degrees C., 140 degrees C., and 200 degrees C. as obtained by Chemical Formula 2.

TABLE 1

| | | | |
|---|---|---|---|
| Wafer | 20 | 140 | 200 |
| temperature(degrees C.) | | | |
| Average stay duration | 7 | 5 × 10⁻⁵ | 1 × 10⁻⁶ |
| of PMDA (sec.) | | | |
| Average stay duration | 2 × 10¹³ | 3 × 10⁴ | 60 |
| of ODA (sec.) | | | |

As shown in Table 1, the average stay time of the PMDA gas and that of the ODA gas greatly differ at the respective wafer temperatures of 20 degrees C., 140 degrees C., and 200 degrees C. Thus, thermal polymerization according to the reaction formula of Chemical Formula 1 greatly changes depending on the wafer temperature and the film formation rate of the polyimide film is also changed. Therefore, in order to continuously stably form the polyimide film, it is important to control the temperature of the wafer W.

In the present embodiment, the temperature of the wafer W is controlled to be within a certain temperature range (e.g., about 200 degrees C.), thereby controlling the film formation rate of the polyimide film. Accordingly, the film formation rate of the polyimide film can be uniform.

Also, in the present embodiment, the set temperature of the supply pipe heating mechanism 77 is controlled to be within a temperature range of 240 to 280 degrees C. higher than the temperature of the wafer W. Thus, the polyimide film can be restrained from being deposited within the supply pipe 73a. As a result, the raw material gases widely spread up to the upper end portion of the supply pipe 73a, and since the raw material gases can be uniformly supplied to the interior of the film forming container 60 from the plurality of supply holes 75, the film formation rate of each wafer can be uniform.

Further, in the present embodiment, the temperature of each wafer mounted in the boat 44 can be uniform by controlling the temperature of the supply pipe heating mechanism 77. Hereinafter, an operational effect will be described.

FIG. 16 is a graph schematically showing a film formation rate of a polyimide film formed on a wafer W and wafer temperature dependency of a deviation of the film formation rate within a plane. In the following description of FIG. 16, the film formation rate refers to an average value of film formation rates within the wafer plane.

As shown in FIG. 16, in an area in which the wafer temperature T is higher than the temperature Topt, the deviation of the film formation rate within the plane is reduced according to an increase in the wafer temperature, and the film formation rate is reduced. Meanwhile, in an area in which the wafer temperature T is lower than the temperature Topt, the deviation of the film formation rate within the plane is remarkably increased according to a decrease in the wafer temperature, and the film formation rate is not increased higher than at the value of the temperature Topt. As a result, in order to enhance the film formation rate and reduce the deviation of the film formation rate within the plane, there is an optimum temperature Topt at the wafer temperature. Namely, it is preferable to control the wafer temperature of each wafer W such that it is equal to the certain temperature Topt.

Similarly, the film formation rate can be enhanced and the deviation of the film formation rate of each wafer can be reduced by also controlling the temperature of the supply pipe heating mechanism 77.

For example, FIG. 17 shows the film formation rate of each wafer when the temperatures of the supply pipe heating mechanism 77 are 240 degrees C., 260 degrees C., and 280 degrees C.

FIG. 17 is a graph showing the film formation rates of the polyimide film formed on each wafer W maintained in the boat 44 when the temperature of the supply pipe heating mechanism 77 is changed. In FIG. 17, the vertical axis represents a film formation rate, indicating a film thickness of the polyimide film formed when a film formation process is performed for a certain period of time. The numbers of wafers W maintained in the boat 44 are assigned at the horizontal axis of FIG. 17 such that they are increased from 1, 2, 3, . . . , starting from the uppermost end side to the lowermost end side.

Also, in FIG. 17, the 53 sheets from the wafer number 3 to the wafer number 55 are determined to be “53-sheet area” and the 37 sheets from the wafer number 11 to the wafer number 47 are determined to be “37-sheet area.” The wafers in the “53-sheet area” include wafers mounted at both of upper and lower sides of the “37-sheet area” in the boat. When the wafer temperature is changed, the deviation of the film thickness (film formation rate) of the polyimide film of each wafer in the “53-sheet area” and the “37-sheet area” is shown by percentage as the difference between a maximum value and a minimum value in Table 2 shown below.

TABLE 2

| Temperature of | Deviation of film | Deviation of film |
|---|---|---|
| supply pipe heating | thickness in 53- | thickness in 37- |
| mechanism (degrees C.) | sheet area (%) | sheet area (%) |
| 240 | ±8.9 | ±5.8 |
| 260 | ±5.5 | ±3.7 |
| 280 | ±19.9 | ±9.7 |

As shown in FIG. 17, as the temperature of the supply pipe heating mechanism 77 is decreased to 280 degrees C., 260 degrees C., and 240 degrees C., the film formation rate in the “37-sheet area” increases. However, as shown in FIG. 17 and Table 2, the deviation of the film formation rate of each wafer in the “37-sheet area” is minimized at 260 degrees C. Thus, in order to reduce the deviation of the film formation rate of each wafer as well as improve the film formation rate, 260 degrees C. is optimal. In this manner, the deviation of the film formation rate of each wafer can be controlled to be reduced by controlling the temperature of the supply pipe heating mechanism 77.

Also, when the supply pipe heating mechanism 77 includes the upper supply pipe heating mechanism 77a and lower supply pipe heating mechanism 77b, the temperature of the upper supply pipe heating mechanism 77a and that of the lower supply pipe heating mechanism 77b are independently controlled to further reduce the deviation of the film formation rate of each wafer.

However, as shown in Table 2, even when the temperature of the supply pipe heating mechanism 77 is 260 degrees C., the deviation of the film formation rate of each wafer is reduced to be ±3.7% at the “37-sheet area,” but is ±5.5% at the “53-sheet area,” and there is a slight deviation in the film formation rate of each wafer.

Thus, in the present embodiment, the heater (substrate heating unit) 62 may be divided into a plurality of zones, and temperature of each zone may be independently controlled. In this case, in addition to controlling the temperature by the supply pipe heating mechanism 77, the temperature is controlled by the heater (substrate heating unit) 62 in each of the plurality of zones. Accordingly, the deviation of the film formation rate at each wafer can be controlled to be further reduced.

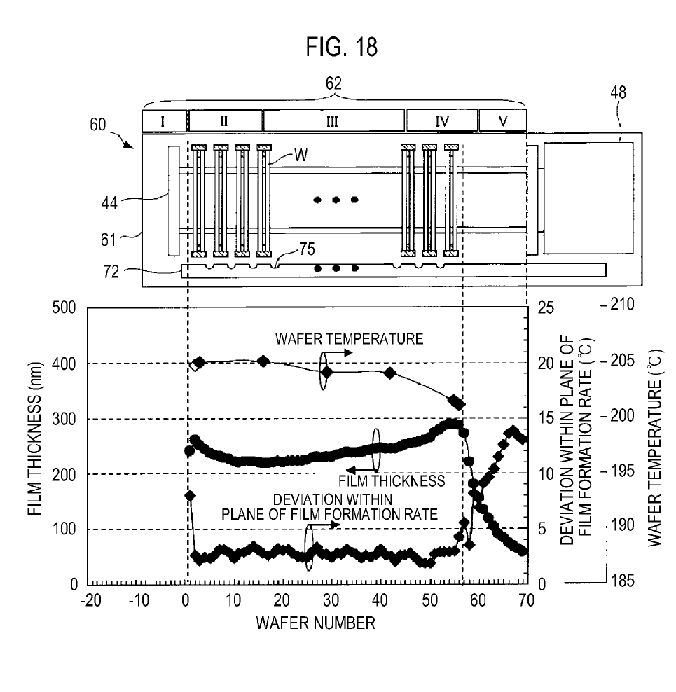

However, simply dividing the heater (substrate heating unit) 62 into a plurality of zones without using the supply pipe heating mechanism 77 cannot make the film formation rate of each wafer uniform. Hereinafter, the case of dividing the heater (substrate heating unit) 62 into a plurality of zones without using the supply pipe heating mechanism 77 will be described as a comparative example with reference to FIG. 18. FIG. 18 is a graph showing a film formation rate (film thickness) of the polyimide film formed on each wafer W maintained in the boat along with a deviation within a plane of the film formation rate, and a wafer temperature in a comparative example. In FIG. 18, the boat 44 accommodated within the film forming container 60 in which the injector 72 is installed is shown above the graph such that the uppermost end side of the boat 44 is at the left side and the lowermost end side of the boat 44 is at the right side. FIG. 18 shows an example in which the heater (substrate heating unit) 62 faces the lowermost end side from the uppermost end side and is divided into five zones of I, II, III, IV, and V.

Likewise, as in FIG. 17, in FIG. 18, a vertical axis represents a film formation rate, indicating a film thickness of the polyimide film formed when a film formation process is performed for a certain period of time. Also, likewise, as in FIG. 17, the numbers of wafers W maintained in the boat 44 are assigned at the horizontal axis of FIG. 18 such that they are increased from 1, 2, 3, . . . , starting from the uppermost end side to the lowermost end side.

As shown in FIG. 18, in the area in which the wafer W number exceeds 50, the film formation rate is increased according to the increase in the number of the wafer W, and then reduced. It is believed that the temperature of the wafer W maintained at the lowermost end side of the boat 44 is changed by the influence of heat such as a warming container 48, or the like.

Meanwhile, according to the present embodiment, the deviation of the film formation rate of each wafer can be controlled to be reduced by controlling the temperature of the supply pipe heating mechanism 77. Also, the deviation of the film formation rate of each wafer can be controlled to be further reduced by independently controlling the temperature of the upper supply pipe heating mechanism 77a and the lower supply pipe heating mechanism 77b.

Further, in the present embodiment, the plurality of wafers W can be maintained in the vertical direction such that an interval between two sheets of vertically neighboring wafers W with rear surfaces Wb thereof facing each other is narrower than the interval between two sheets of vertically neighboring wafers W with surfaces Wa thereof facing each other. Accordingly, in a state in which the number of wafers W mounted in the boat 44 is fixed, the interval of two sheets of the vertically neighboring wafers W with surfaces Wa thereof facing each other can be increased. As a result, the gap between the surface Wa of one wafer W and the surface Wa of the other wafer W can be increased, thus allowing the supply of a sufficient amount of raw material gases to the surface of the wafers W.

Also, in the present embodiment, the support ring 55 may have a spacer unit 55b installed to block the gap between two sheets of the vertically neighboring wafers W with rear surfaces Wb thereof facing each other. Accordingly, when a film is formed within the film forming container 60, raw material gases can be prevented from being introduced between two sheets of wafers W with the rear surfaces Wb thereof facing each other to form a film on the rear surfaces Wb of the wafers W.

Thereafter, in step S14, a supply of the PMDA gas from the first raw material gas supply unit 71a and a supply of the ODA gas from the second raw material gas supply unit 71b are stopped and the interior of the film forming container 60 is recovered to the atmospheric pressure (pressure recovering process). The exhaust capability of the exhaust device 86 or a flow rate adjustment valve (not shown) installed between the exhaust device 86 and the film forming container 60 is adjusted to reduce the exhaust volume of exhausting the film forming container 60, thus recovering the interior of the film forming container 60 into, for example, the atmospheric pressure (760 Torr) from, for example, 0.3 Torr.

Next, in step S15, the wafers W are unloaded from the film forming container 60 (unloading process). In the example of the film forming apparatus 10 illustrated in FIGS. 1 to 4, for example, the cover 43 with the boat 44a loaded thereon is lowered by the lifting mechanism 46 so as to be unloaded to the loading area 40 from the interior of the film forming container 60. Then, the wafers W are moved to be mounted in the receiving container 21 from the boat 44a loaded on the cover 43, unloaded by the movement mounting mechanism 47, thereby unloading the wafers W from the film forming container 60. Thereafter, the film formation processing is terminated.

Further, when film formation processing is continuously performed on a plurality of batches, in the loading area 40, the wafers W are moved to be mounted on the boat 44 from the receiving container 21 by the movement mounting mechanism 47, and the process again returns to step S11 in which film formation processing is performed on a next batch.

As described above, in the present embodiment, the film forming apparatus 10 can have two boats. Thus, step S11 of the rear batch can be performed immediately after step S15 of the front batch. Namely, before step S15 of the front batch, the wafers W of the rear batch can be moved from the receiving container 21 and mounted on the boat 44b so as to be ready. Further, in step S15 of the front batch, immediately after the boat 44a is unloaded from the film forming container 60, the boat 44b with the wafers W of the rear batch mounted thereon can be loaded into the film forming container 60. Accordingly, a time (tact time) required for film formation processing can be shortened, thus reducing fabrication cost.

### First Modification of First Embodiment

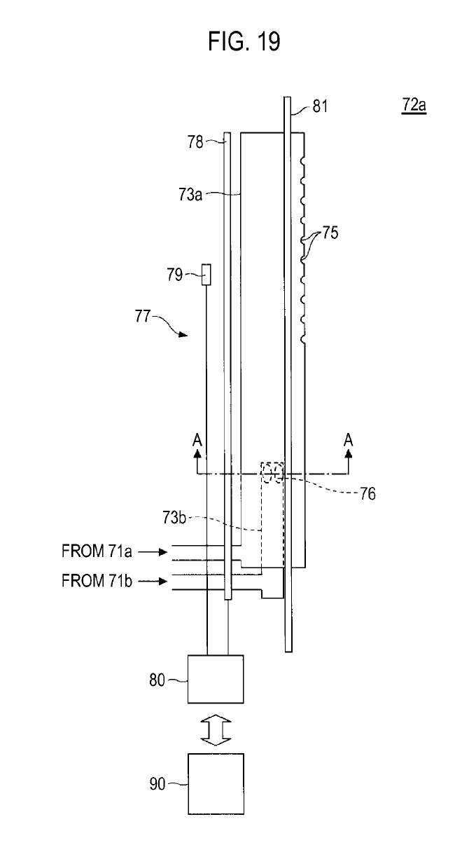

A film forming apparatus according to a first modification of the first embodiment of the present disclosure will now be described with reference to FIGS. 19 to 21.

The film forming apparatus according to the present modification is different from the film forming apparatus 10 according to the first embodiment, in that the supply mechanism 70 includes a shielding plate 81 in order to prevent the wafer W maintained in the boat 44 from being heated by the supply pipe heating mechanism 77. Also, the film forming apparatus according to the present modification is different from the film forming apparatus 10 according to the first embodiment, in that only one supply pipe heating mechanism 77, rather than a plurality of supply pipe heating mechanisms, is provided. The other portions of the film forming apparatus according to the present modification are the same as those of the film forming apparatus 10 according to the first embodiment, so descriptions thereof will be omitted.

FIG. 19 is a side view showing an injector 72a according to the present modification.

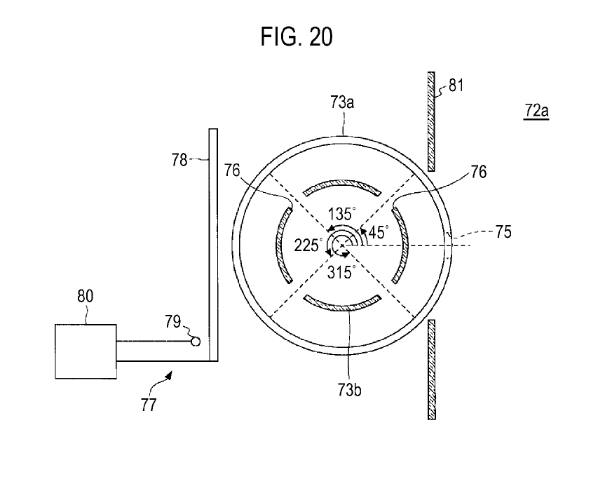

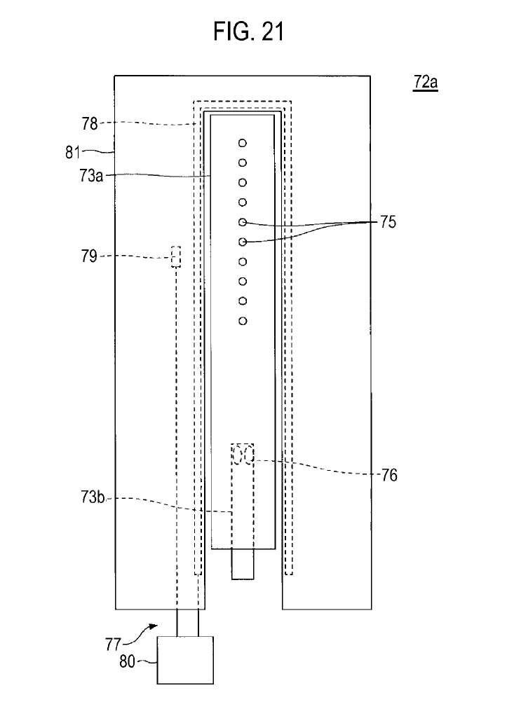

FIG. 20 is a sectional view taken along line A-A in FIG. 19. FIG. 21 is a front view of the injector 72a illustrated in FIG. 19. FIG. 20 is a front view of the injector 72a viewed from the side of the boat 44.

The injector 72a includes a supply pipe 73a and an inner supply pipe 73b. The supply pipe 73a and the inner supply pipe 73b are the same as the supply pipe 73a and the inner supply pipe 73b in the film forming apparatus 10 according to the first embodiment, so a description thereof will be omitted.

In the present modification, the injector 72a includes the shielding plate 81 for preventing the wafer W maintained in the boat 44 from being heated by the supply pipe heating mechanism 77. As shown in FIGS. 19 to 21, the shielding plate 81 is installed at the opposite side from the supply pipe heating mechanism 77 of the center of the supply pipe 73a. Also, the shielding plate 81 is installed to cover the heater 78 when viewed from the boat 44 side. Accordingly, the wafer W maintained in the boat 44 can be more reliably prevented from being heated by the heater 78.

Also, in the present modification, only one supply pipe heating mechanism 77 is installed. Even with this configuration, the first and second raw material gases flowing in the supply pipe 73a can be heated at a temperature (e.g., 240 to 280 degrees C.) higher than the temperature range (e.g., about 200 degrees C.) in which thermal polymerization takes place. Accordingly, the polyimide film generated as the first and second raw material gases are thermally polymerized can be prevented from being deposited on the inner wall of the supply pipe 73a or in the vicinity of the supply holes 75.

Also, in the present modification, the controller 90 heats the wafer W maintained in the boat 44 (substrate maintaining unit) within the temperature range in which thermal polymerization takes place by the heater (substrate heating unit) 62, to control the film formation rate of the polyimide film. Accordingly, the film formation rate of the polyimide film as formed can become uniform.

Also, in the present modification, the deviation of the film formation rate of each wafer can be controlled to be reduced by controlling the temperature of the supply pipe heating mechanism 77. Further, since the wafer W maintained in the boat 44 can be prevented from being heated by the supply pipe heating mechanism 77, by virtue of the shielding plate 81, the deviation of the film formation rate of each wafer can also be controlled to be reduced.

Also, in the present modification, the heater (substrate heating unit) 62 may be divided into a plurality of zones, and the temperature of each zone may be independently controlled. In this case, in addition to controlling the temperature by the supply pipe heating mechanism 77, the temperature of each zone is controlled by the heater (substrate heating unit) 62. Also, the wafer W maintained in the boat 44 can be prevented from being heated by the supply pipe heating mechanism 77, by the presence of the shielding plate 81. Accordingly, the deviation of the film formation rate of each wafer can be controlled to be further reduced.

### Second Modification of First Embodiment

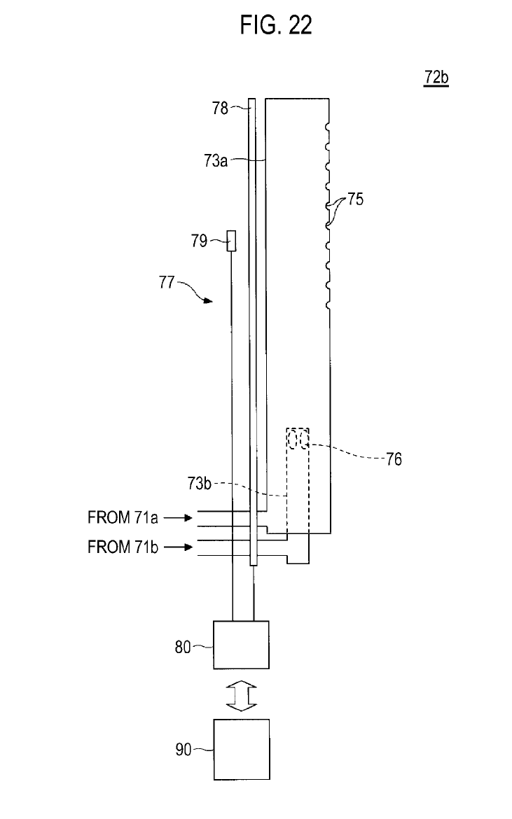

A film forming apparatus according to a second modification of the first embodiment of the present disclosure will now be described with reference to FIG. 22.

The film forming apparatus according to the present modification is different from the film forming apparatus 10 according to the first embodiment, in that only one supply pipe heating mechanism 77, rather than a plurality of supply pipe heating mechanisms, is provided. The other portions of the film forming apparatus according to the present modification are the same as those of the film forming apparatus 10 according to the first embodiment, so descriptions thereof will be omitted.

FIG. 22 is a side view showing an injector 72b according to the present modification. The injector 72b includes a supply pipe 73a and an inner supply pipe 73b. The supply pipe 73a and the inner supply pipe 73b are the same as the supply pipe 73a and the inner supply pipe 73b in the film forming apparatus 10 according to the first embodiment, respectively, so a description thereof will be omitted.

In the present modification, only one supply pipe heating mechanism 77 is installed. Even with this configuration, the first and second raw material gases flowing in the supply pipe 73a can be heated at a temperature (e.g., 240 to 280 degrees C.) higher than the temperature range (e.g., about 200 degrees C.) in which thermal polymerization takes place. Accordingly, the polyimide film generated as the first and second raw material gases are thermally polymerized can be prevented from being deposited on the inner wall of the supply pipe 73a or in the vicinity of the supply holes 75.

Also, in the present modification, the controller 90 heats the wafer W maintained in the boat 44 (substrate maintaining unit) within the temperature range in which thermal polymerization takes place by the heater (substrate heating unit) 62, to control the film formation rate of the polyimide film. Accordingly, the film formation rate of the polyimide film as formed can become uniform.

### Second Embodiment

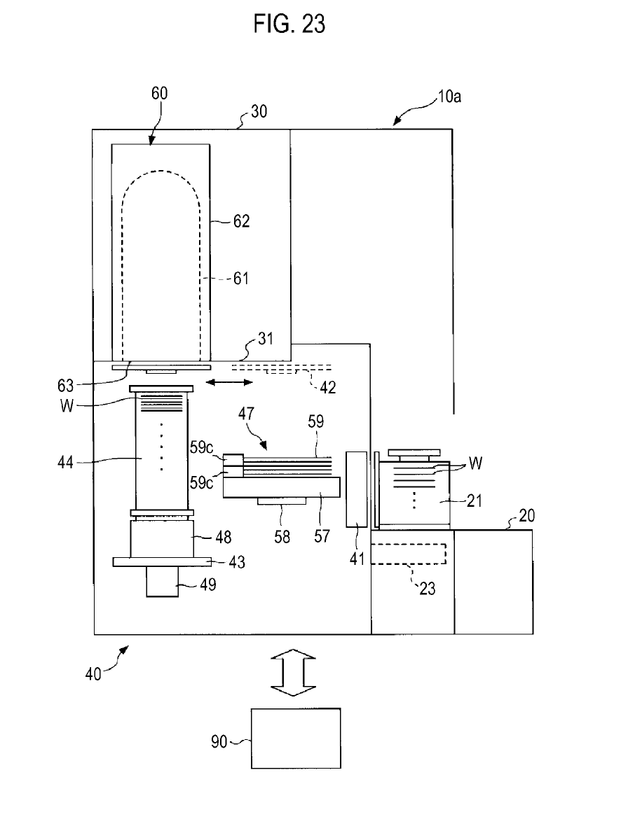

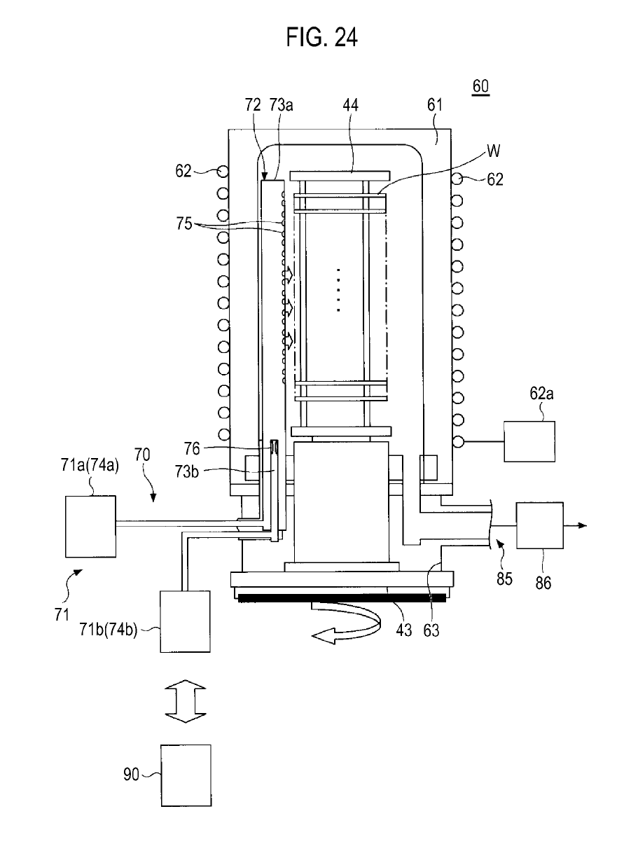

A film forming apparatus according to a second embodiment of the present disclosure will now be described with reference to FIGS. 23 and 24.

A film forming apparatus 10a according to the present embodiment is different from the film forming apparatus 10 according to the first embodiment, in that the film forming apparatus 10a includes only one boat. In addition, the film forming apparatus 10a according to the present embodiment is different from the film forming apparatus 10 according to the first embodiment, in that the boat 44 maintains a plurality of wafers W in the vertical direction such that neither rear surfaces Wb nor surfaces Wa of vertically neighboring wafers W face each other. Also, the film forming apparatus 10a according to the present embodiment is different from the film forming apparatus 10 according to the first embodiment, in that only the first raw material gas is supplied. Other portions of the film forming apparatus 10a according to the present embodiment are the same as those of the film forming apparatus 10 according to the first embodiment, so descriptions thereof will be omitted.

FIG. 23 is a vertical sectional view schematically showing a film forming apparatus 10a according to the present embodiment. FIG. 24 is a sectional view schematically showing the configuration of a film forming container 60, a supply mechanism 70, and an exhaust mechanism 85.

The film forming apparatus 10a includes a loading table (load port) 20, a housing 30, and a controller 90. Also, the housing 30 has a loading area (operation area) 40, and a film forming container 60. The positional relationships among the loading table (load port) 20, the housing 30, the loading area 40, and the film forming container 60 are the same as those of the film forming apparatus 10 according to the first embodiment.

The loading table (load port) 20 may be the same as the loading table 20 of the film forming apparatus 10 according to the first embodiment, except that a receiving container for receiving a support ring is not loaded thereon.

A door mechanism 41, a shutter mechanism 42, a cover 43, a boat 44, a lifting mechanism 46, and a movement mounting mechanism 47 are installed in the loading area (operation area) 40. Portions other than the cover 43, the boat 44, and the movement mounting mechanism 47 may be the same as those of the film forming apparatus 10 according to the first embodiment.

As for the cover 43 and the boat 44, they are different from the loading table 20 of the film forming apparatus 10 according to the first embodiment in that only a single boat 44 is provided and the boat 44 is constantly loaded on the cover 43. That is, the bases 45a and 45b and the boat transfer mechanism 45c, which are installed in the film forming apparatus 10 according to the first embodiment, may not be installed.

The boat 44 may be the same as the boat 44 illustrated in FIG. 4, and a plurality of pillars, for example, three pillars 52, are interposed between the ceiling plate 50 and the bottom plate 51. The hook portion 53 for maintaining the wafers W is installed on the pillars 52. In this case, in the present embodiment, among the plurality of wafers W, any wafer W is mounted in a state in which its surface Wa is used as a lower surface or an upper surface. Thus, the present embodiment is different from the first embodiment, and the same number of hook portions 53 as that of the sheets of the mounted wafers W are installed. Therefore, in order to mount the same number of sheets of wafers W as that of the first embodiment, hook portions 53 which are double the number of hook portions 53 in the first embodiment are installed in the boat 44 at half intervals of the intervals of the hook portions 53 in the first embodiment.

The movement mounting mechanism 47 includes a base 57, a lifting arm 58, and a plurality of forks (movement mounting plates) 59. In the present embodiment, a vertically reversible upper fork may not be provided, and the plurality of forks 59 may be installed to be only horizontally movable by the moving body 59c.

The film forming container 60, the supply mechanism 70, the exhaust mechanism 85, and the controller 90 are the same as those of the first embodiment.

In the present embodiment, the controller 90 heats the wafer W maintained in the boat 44 (substrate maintaining unit) within the temperature range (e.g., about 200 degrees C.) in which thermal polymerization takes place by the heater (substrate heating unit) 62, to control the film formation rate of the polyimide film. Accordingly, the film formation rate of the polyimide film as formed can become uniform.

Also, in the present embodiment, the first and second raw material gases flowing in the supply pipe 73a can be heated at a temperature (e.g., 240 to 280 degrees C.) higher than the temperature range (e.g., about 200 degrees C.) in which thermal polymerization takes place. Accordingly, the polyimide film generated as the first and second raw material gases are thermally polymerized can be prevented from being deposited on the inner wall of the supply pipe 73a or in the vicinity of the supply holes 75.

Also, in the present embodiment, the supply mechanism 70 may include a shielding plate 81 for preventing the wafer W maintained in the boat 44 from being heated by the supply pipe heating mechanism 77. Also, in the present embodiment, only one supply pipe heating mechanism 77, rather than a plurality of supply pipe heating mechanisms, may be provided.

According to the present disclosure in some embodiments, it is possible to make the film formation rate of the polyimide film formed by thermal polymerization of aromatic acid dianhydride and aromatic diamine uniform.

While certain embodiments have been described, these embodiments have been presented by way of example only, and are not intended to limit the scope of the disclosures. Indeed, the novel methods and apparatuses described herein may be embodied in a variety of other forms; furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus for forming a polyimide film on a substrate by supplying a first raw material gas formed as aromatic acid dianhydride and a second raw material gas formed as aromatic diamine to the substrate maintained within a film forming container, and thermally polymerizing the supplied first and second raw material gases on a surface of the substrate, the apparatus comprising:
a substrate maintaining unit configured to maintain the substrate within the film forming container;
a substrate heating unit configured to heat the substrate maintained in the substrate maintaining unit;
a supply mechanism installed within the film forming container, and configured to include a supply pipe with supply holes for supplying the first and second raw material gases to the interior of the film forming container through the supply holes; and
a controller configured to control the substrate maintaining unit, the substrate heating unit, and the supply mechanism,
wherein the controller supplies the first and second raw material gases by the supply mechanism and simultaneously heats the substrate maintained in the substrate maintaining unit within a temperature range in which thermal polymerization takes place, by the substrate heating unit, to control a film formation rate of the polyimide film.

2. The apparatus of claim 1, wherein the supply mechanism includes a supply pipe heating mechanism configured to heat the first and second raw material gases flowing in the supply pipe at a temperature higher than the temperature range in which thermal polymerization takes place.

3. The apparatus of claim 2, wherein the substrate maintaining unit maintains a plurality of substrates at certain maintaining intervals in a vertical direction,
the supply pipe is installed to extend in the vertical direction and has a plurality of supply holes formed thereon, and
the supply pipe heating mechanism is a plurality of supply pipe heating mechanisms which are disposed in a vertical direction and whose temperature can be independently controlled.

4. The apparatus of claim 3, wherein the substrate maintaining unit maintains the plurality of substrates in the vertical direction such that rear surfaces of vertically neighboring substrates face each other or the surfaces of vertically neighboring substrates face each other, and the interval between two sheets of the vertically neighboring substrates with the rear surfaces thereof facing each other is narrower than the interval between two sheets of the vertically neighboring substrates with the surfaces thereof facing each other.

5. The apparatus of claim 4, wherein the substrate maintaining unit has a blocking member configured to block a gap between two sheets of the vertically neighboring substrates with rear surfaces thereof facing each other.

6. The apparatus of claim 2, wherein the supply mechanism includes an inner supply pipe accommodated at a portion of an upstream side than the portion of the supply pipe where the supply holes are formed and having an opening for supplying any one of the first and second raw material gases formed thereon, the supply mechanism making the one raw material gas flowing in the inner supply pipe join with the other raw material gas of the first and second raw material gases flowing in the supply pipe through the opening so as to be mixed, and supplying the mixed first and second raw material gases to the interior of the film forming container through the supply holes.

7. The apparatus of claim 6, wherein the opening faces a direction different from the direction of the supply holes when viewed from the section perpendicular to the direction in which the supply pipe extends.

8. The apparatus of claim 1, wherein the aromatic acid dianhydride is pyromellitic dianhydride and the aromatic diamine is 4,4′-diaminodiphenylether.
